(19) United States
(12) Patent Application Publication
(10) Pub. No.: US 2006/0225772 A1
(43) Pub. Date: Oct. 12, 2006

(54) Controlled pressure differential in a high-pressure processing chamber

(76) Inventor: William D. Jones, Phoenix, AZ (US)

Correspondence Address: HAVERSTOCK & OWENS LLP, 162 NORTH WOLFE ROAD, SUNNYVALE, CA, 94086, US

(21) Appl. No.: 11/093,944

(22) Filed: Mar. 29, 2005

(51) Int. Cl. B08B 3/00; H01L 21/306

(52) U.S. Cl. 134/56 R; 156/345.13

(57) ABSTRACT

A method and apparatus for controlling a pressure differential in a high pressure processing chamber are disclosed. The pressure differential is related to a difference between a pressure generated within the high pressure processing chamber and a sealing force for maintaining the high-pressure processing chamber. By maintaining the pressure differential within a predefined range, contaminants produced when forming and maintaining the processing chamber are reduced or eliminated.

### CROSS-REFERENCE TO RELATED APPLICATIONS

This patent application is related to commonly owned co-pending U.S. patent application Ser. No. 10/364,284, filed Feb. 10, 2003, and titled “High-Pressure Processing Chamber for a Semiconductor Wafer”, which is hereby incorporated by reference in its entirety.

### FIELD OF THE INVENTION

The present invention relates to the field of processing chambers. More particularly, the present invention relates to minimizing a deflection of a platen during the processing of a semiconductor wafer and thereby preventing or reducing the formation of particles due to wear on surfaces that come into contact with each other during semiconductor wafer processing.

### BACKGROUND OF THE INVENTION

The use of chambers for processing semiconductor wafers is known. For example, the owner of this application has proposed processing chambers for use in cleaning semiconductor wafers with supercritical fluids. Generally, processing chambers comprise a first housing chamber and a second housing chamber. When the two housing chambers are brought together, they form a processing volume in which a wafer is contained during processing. During processing, it is desirable that the processing volume remain sealed so that the desired operating conditions are maintained within the processing volume during processing. According to previous embodiments proposed by the owner hereof, a processing volume is maintained by applying a sealing force sufficient to counteract a reactive force of the processing fluid within the processing chamber. The sealing force can be produced by a piston force system.

During processing, the wafer is supported by a wafer support structure such as a platen. When the processing volume is formed, the platen meets the first chamber housing at its edges at respective sealing surfaces. The piston force system drives the platen. One problem is that the force of the piston can cause the platen to bend or bow. Even a small amount of deflection of the platen can cause the platen and the wafer to move relative to one another. The deflection can also cause sealing surfaces to move relative to each other.

Where some relative motion occurs between surfaces that come into contact with each other during processing there can be wear on the surfaces, which can produce particles. These particles can get onto the surface of the wafer. It is well known in the industry that particulate surface contamination of semiconductor wafers typically degrades device performance and negatively affects yield. When processing wafers, it is desirable that the number of particles and contaminants be minimized.

What is needed is an effective means to reduce or eliminate the formation of particles due to wear on surfaces that meet each other during semiconductor wafer processing using processing chambers. What is also needed is an effective means to minimize the deflection of the wafer support structure such as a platen during semiconductor wafer processing.

### SUMMARY OF THE INVENTION

The invention includes a high-pressure processing system for processing a substrate within a high-pressure processing chamber. The system includes a recirculation loop that can comprise the high-pressure processing chamber and a high-pressure recirculation system coupled to the high-pressure processing chamber. The high-pressure processing chamber can include a first chamber assembly and a second chamber assembly, and the second chamber assembly can include a platen that includes a region for supporting the substrate. The system can also include a drive mechanism for forming the high-pressure processing chamber that includes means for moving the second chamber assembly in and out of contact with the first chamber assembly and means for applying a sealing force when the second chamber assembly is in contact with the first chamber assembly. In addition, the system can include a high-pressure fluid supply system coupled to the recirculation loop and includes means for pressurizing the recirculation loop using a high-pressure fluid. The system can include a pressure compensator that is coupled to the drive mechanism and is used for controlling a pressure differential. Furthermore, the system can include a controller coupled to the recirculation loop, the drive mechanism, the high-pressure fluid supply system, and the pressure compensator, the controller having means for comparing the pressure differential to a threshold and having means for controlling the pressure differential.

Another embodiment provides a method of processing a substrate within a high-pressure processing system, the method includes positioning a substrate on a substrate holder; applying a sealing force to bring a first chamber housing into contact with a second chamber housing to form a processing chamber; pressurizing the processing chamber using a high-pressure fluid; determining a pressure differential using the sealing force and a pressure within the processing chamber; and comparing the pressure differential to a threshold and substantially balancing the sealing force relative to the pressure within the processing chamber during processing of a wafer.

### BRIEF DESCRIPTION OF THE DRAWINGS

A more complete appreciation of various embodiments of the invention and many of the attendant advantages thereof will become readily apparent with reference to the following detailed description, particularly when considered in conjunction with the accompanying drawings, in which:

FIG. 1 shows an exemplary block diagram of a processing system in accordance with an embodiment of the invention;

FIG. 2 is a schematic illustration one embodiment of an apparatus for processing a substrate with a processing fluid in accordance with embodiments of the invention;

FIG. 3 illustrates a simplified block diagram of a balancing means in accordance with an embodiment of the invention;

FIG. 4 illustrates a simplified block diagram of a pneumatic controller in accordance with an embodiment of the invention;

FIG. 5 illustrates an exemplary graph of pressure versus time for a supercritical process in accordance with an embodiment of the invention; and

FIG. 6 illustrates a flow diagram of a method of operating a pressure compensator in accordance with an embodiment of the invention

### DETAILED DESCRIPTION OF SEVERAL EMBODIMENTS

The present invention is directed to an apparatus for and methods of minimizing the deflection of a wafer platen while effectively and securely maintaining a processing volume during the processing of a semiconductor wafer with a pressurized fluid. For the purposes of the invention and this disclosure, “fluid” means a gaseous, liquid, supercritical, and/or near-supercritical fluid. In certain embodiments of the invention, “fluid” means gaseous, liquid, supercritical, and/or near-supercritical carbon dioxide. It should be appreciated that solvents, co-solvents, chemistries, and/or surfactants can be contained in or added to the fluid including to carbon dioxide. For purposes of the invention, “carbon dioxide” should be understood to refer to carbon dioxide (CO2) employed as a fluid in a liquid, gaseous or supercritical (including near supercritical) state. “Supercritical carbon dioxide” refers herein to CO2 at conditions above the critical temperature (30.5 C.) and critical pressure (7.38 MPa). When CO2 is subjected to pressures and temperatures above 7.38 MPa and 30.5 C., respectively, it is determined to be in the supercritical state. “Near-supercritical carbon dioxide” refers to CO2 within about 85% of critical temperature and critical pressure. For the purposes of the invention and this disclosure, “substrate” typically refers to a semiconductor wafer for forming integrated circuits, and can include a wide variety of structures such as semiconductor device structures and/or electro-mechanical system (MEMS) devices typically with a deposited photoresist or residue. A substrate can be a single layer of material, such as a silicon wafer, or can include any number of layers. A substrate can comprise various materials, including semiconductors, insulators, metals, ceramics, glass, or compositions thereof.

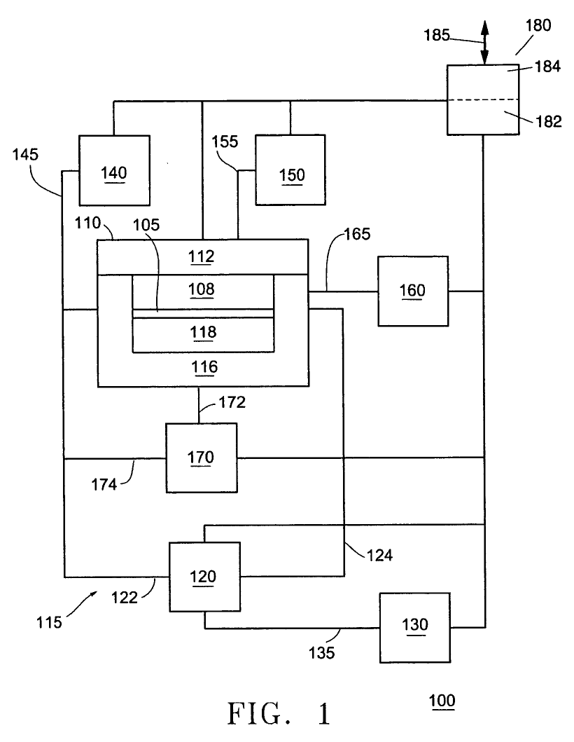

FIG. 1 shows an exemplary block diagram of a processing system in accordance with an embodiment of the invention. In the illustrated embodiment, processing system 100 comprises a process module 110, a recirculation system 120, a process chemistry supply system 130, a high-pressure fluid supply system 140, an exhaust control system 150, a pressure control system 160, a pressure compensator 170, and a controller 180. The processing system 100 can operate at pressures that can range from 1000 psi. to 10,000 psi. In addition, the processing system 100 can operate at temperatures that can range from 40 to 300 degrees Celsius.

The details concerning one example of a processing chamber are disclosed in co-owned and co-pending U.S. patent applications, Ser. No. 09/912,844, entitled “HIGH PRESSURE PROCESSING CHAMBER FOR SEMICONDUCTOR SUBSTRATE,” filed Jul. 24, 2001, Ser. No. 09/970,309, entitled “HIGH PRESSURE PROCESSING CHAMBER FOR MULTIPLE SEMICONDUCTOR SUBSTRATES,” filed Oct. 3, 2001, Ser. No. 10/121,791, entitled “HIGH PRESSURE PROCESSING CHAMBER FOR SEMICONDUCTOR SUBSTRATE INCLUDING FLOW ENHANCING FEATURES,” filed Apr. 10, 2002, and Ser. No. 10/364,284, entitled “HIGH-PRESSURE PROCESSING CHAMBER FOR A SEMICONDUCTOR WAFER,” filed Feb. 10, 2003, the contents of which are incorporated herein by reference.

The controller 180 can be coupled to the process module 110, the recirculation system 120, the process chemistry supply system 130, the high-pressure fluid supply system 140, the exhaust control system 150, the pressure control system 160, and the pressure compensator 170. Alternatively, controller 180 can be coupled to one or more additional controllers/computers (not shown), and controller 180 can obtain setup and/or configuration information from an additional controller/computer.

In FIG. 1, singular processing elements (110, 120, 130, 140, 150, 160, 170, and 180) are shown, but this is not required for the invention. The semiconductor processing system 100 can comprise any number of processing elements having any number of controllers associated with them in addition to independent processing elements.

The controller 180 can be used to configure any number of processing elements (110, 120, 130, 140, 150, 160, 170), and the controller 180 can collect, provide, process, store, and display data from processing elements. The controller 180 can comprise any number of applications for controlling one or more of the processing elements. For example, controller 180 can include a GUI component (not shown) that can provide easy to use interfaces that enable a user to monitor and/or control one or more processing elements.

The process module 110 can include an upper assembly 112 and a lower assembly 116, and the upper assembly 112 can be coupled to the lower assembly 116 to form a processing chamber 108 for holding a substrate 105 during processing. In an alternative embodiment, a frame and/or injection ring may be included and may be coupled to an upper assembly and/or a lower assembly. The upper assembly 112 can comprise a heater (not shown) for heating the processing chamber 108, the substrate 105, or the processing fluid, or a combination of two or more thereof. Alternatively, a heater is not required in the upper assembly 112. In another embodiment, the lower assembly 116 can comprise a heater (not shown) for heating the processing chamber 108, the substrate, or the processing fluid, or a combination of two or more thereof. The process module 110 can include means for flowing a processing fluid through the processing chamber 108. In one example, a circular flow pattern can be established, and in another example, a substantially linear flow pattern can be established. Alternatively, the means for flowing can be configured differently. The lower assembly 116 can comprise one or more lifters (not shown) for moving a chuck 118 coupled to the lower assembly 116 and/or the substrate 105. Alternatively, a lifter is not required.

In one embodiment, the process module 110 can include a holder or chuck 118 for supporting and holding the substrate 105 while processing the substrate 105. The holder or chuck 118 can also be configured to heat or cool the substrate 105 before, during, and/or after processing the substrate 105. Alternatively, the process module 110 can include a platen for supporting and holding the substrate 105 while processing the substrate 105.

A transfer system (not shown) can be used to move the substrate 105 into and out of the processing chamber 108 through a slot (not shown). In one example, the slot can be opened and closed by moving the chuck, and in another example, the slot can be controlled using a gate valve.

The substrate 105 can include semiconductor material, metallic material, dielectric material, ceramic material, or polymeric material, or a combination of two or more thereof. The semiconductor material can include Si, Ge, Si/Ge, or GaAs. The metallic material can include Cu, Al, Ni, Pb, Ti, Ta, or W, or combinations of two or more thereof. The dielectric material can include Si, O, N, H, P, or C, or combinations of two or more thereof. The ceramic material can include Al, N, Si, C, or O, or combinations of two or more thereof.

In one embodiment, the recirculation system 120 can be coupled to the process module 110 using one or more inlet lines 122 and one or more outlet lines 124, and a recirculation loop 115 can be configured that includes a portion of the recirculation system 120, a portion of the process module 110, one or more of the inlet lines 122, and one or more of the outlet lines 124. In one embodiment, the recirculation loop 115 comprises a volume of approximately one liter. In alternative embodiments, the volume of the recirculation loop 115 can vary from approximately 0.5 liters to approximately 2.5 liters.

The recirculation system 120 can comprise one or more pumps (not shown) used to regulate the flow of the supercritical processing solution through the processing chamber 108 and the other elements in the recirculation loop 115. The flow rate can vary from approximately 0.01 liters/minute to approximately 100 liters/minute.

The recirculation system 120 can comprise one or more valves (not shown) for regulating the flow of a supercritical processing solution through the recirculation loop 115. For example, the recirculation system 120 can comprise any number of back-flow valves, filters, pumps, and/or heaters (not shown) for maintaining a supercritical processing solution and flowing the supercritical processing solution through the recirculation system 120 and through the processing chamber 108 in the process module 110.

Processing system 100 can comprise the chemistry supply system 130. In the illustrated embodiment, the chemistry supply system 130 is coupled to the recirculation system 120 using one or more lines 135, but this is not required for the invention. In alternative embodiments, the chemical supply system 130 can be configured differently and can be coupled to different elements in the processing system.

The process chemistry is introduced by the process chemistry supply system 130 into the fluid introduced by the high-pressure fluid supply system 140 at ratios that vary with the substrate properties, the chemistry being used, and the process being performed in the process module 110. The ratio can vary from approximately 0.001 to approximately 15 percent by volume. For example, when the recirculation loop 115 comprises a volume of about one liter, the process chemistry volumes can range from approximately ten microliters to approximately one hundred fifty milliliters. In alternative embodiments, the volume and/or the ratio may be higher or lower.

The chemistry supply system 130 can comprise a cleaning chemistry assembly (not shown) for providing cleaning chemistry for generating supercritical cleaning solutions within the processing chamber 108. The cleaning chemistry can include peroxides and a fluoride source. Further details of fluoride sources and methods of generating supercritical processing solutions with fluoride sources are described in U.S. patent application Ser. No. 10/442,557, filed May 10, 2003, and titled “TETRA-ORGANIC AMMONIUM FLUORIDE AND HF IN SUPERCRITICAL FLUID FOR PHOTORESIST AND RESIDUE REMOVAL”, and U.S. patent application Ser. No. 10/321,341, filed Dec. 16, 2002, and titled “FLUORIDE IN SUPERCRITICAL FLUID FOR PHOTORESIST POLYMER AND RESIDUE REMOVAL,” both incorporated by reference herein.

In addition, the cleaning chemistry can include chelating agents, complexing agents, oxidants, organic acids, and inorganic acids that can be introduced into supercritical carbon dioxide with one or more carrier solvents, such as N,N-dimethylacetamide (DMAc), gamma-butyrolactone (BLO), dimethyl sulfoxide (DMSO), ethylene carbonate (EC), N-methylpyrrolidone (NMP), dimethylpiperidone, propylene carbonate, and alcohols (such a methanol, ethanol and 1-propanol).

The chemistry supply system 130 can be configured to introduce N-methyl pyrrolidone (NMP), diglycol amine, hydroxyl amine, di-isopropyl amine, tri-isoprpyl amine, tertiary amines, catechol, ammonium fluoride, ammonium bifluoride, methylacetoacetamide, ozone, propylene glycol monoethyl ether acetate, acetylacetone, dibasic esters, ethyl lactate, CHF₃, BF₃, HF, other fluorine containing chemicals, or any mixture thereof. Other chemicals such as organic solvents may be utilized independently or in conjunction with the above chemicals to remove organic materials. The organic solvents may include, for example, an alcohol, ether, and/or glycol, such as acetone, diacetone alcohol, dimethyl sulfoxide (DMSO), ethylene glycol, methanol, ethanol, propanol, or isopropanol (IPA). For further details, see U.S. Pat. No. 6,306,564B1, filed May 27, 1998, and titled “REMOVAL OF RESIST OR RESIDUE FROM SEMICONDUCTORS USING SUPERCRITICAL CARBON DIOXIDE”, and U.S. Pat. No. 6,509,141B2, filed Sep. 3, 1999, and titled “REMOVAL OF PHOTORESIST AND PHOTORESIST RESIDUE FROM SEMICONDUCTORS USING SUPERCRITICAL CARBON DIOXIDE PROCESS”, both incorporated by reference herein.

Moreover, the chemistry supply system 130 can be configured to introduce a peroxide during a cleaning and/or rinsing process. The peroxide can be introduced with any one of the above process chemistries, or any mixture thereof. The peroxide can include organic peroxides, or inorganic peroxides, or a combination thereof. For example, organic peroxides can include 2-butanone peroxide; 2,4-pentanedione peroxide; peracetic acid; t-butyl hydroperoxide; benzoyl peroxide; or m-chloroperbenzoic acid (mCPBA). Other peroxides can include hydrogen peroxide. Alternatively, the peroxide can include a diacyl peroxide, such as: decanoyl peroxide; lauroyl peroxide; succinic acid peroxide; or benzoyl peroxide; or any combination thereof. Alternatively, the peroxide can include a dialkyl peroxide, such as: dicumyl peroxide; 2,5-di(t-butylperoxy)-2,5-dimethylhexane; t-butyl cumyl peroxide; α,α-bis(t-butylperoxy)diisopropylbenzene mixture of isomers; di(t-amyl) peroxide; di(t-butyl) peroxide; or 2,5-di(t-butylperoxy)-2,5-dimethyl-3-hexyne; or any combination thereof. Alternatively, the peroxide can include a diperoxyketal, such as: 1,1-di(t-butylperoxy)-3,3,5-trimethylcyclohexane; 1,1-di(t-butylperoxy)cyclohexane; 1,1-di(t-amylperoxy)-cyclohexane; n-butyl 4,4-di(t-butylperoxy)valerate; ethyl 3,3-di-(t-amylperoxy)butanoate; t-butyl peroxy-2-ethylhexanoate; or ethyl 3,3-di(t-butylperoxy)butyrate; or any combination thereof. Alternatively, the peroxide can include a hydroperoxide, such as: cumene hydroperoxide; or t-butyl hydroperoxide; or any combination thereof. Alternatively, the peroxide can include a ketone peroxide, such as: methyl ethyl ketone peroxide; or 2,4-pentanedione peroxide; or any combination thereof. Alternatively, the peroxide can include a peroxydicarbonate, such as: di(n-propyl)peroxydicarbonate; di(sec-butyl)peroxydicarbonate; or di(2-ethylhexyl)peroxydicarbonate; or any combination thereof. Alternatively, the peroxide can include a peroxyester, such as: 3-hydroxyl-1,1-dimethylbutyl peroxyneodecanoate; α-cumyl peroxyneodecanoate; t-amyl peroxyneodecanoate; t-butyl peroxyneodecanoate; t-butyl peroxypivalate; 2,5-di(2-ethylhexanoylperoxy)-2,5-dimethylhexane; t-amyl peroxy-2-ethylhexanoate; t-butyl peroxy-2-ethylhexanoate; t-amyl peroxyacetate; t-butyl peroxyacetate; t-butyl peroxybenzoate; OO-(t-amyl) O-(2-ethylhexyl)monoperoxycarbonate; OO-(t-butyl) O-isopropyl monoperoxycarbonate; OO-(t-butyl) O-(2-ethylhexyl) monoperoxycarbonate; polyether poly-t-butylperoxy carbonate; or t-butyl peroxy-3,5,5-trimethylhexanoate; or any combination thereof. Alternatively, the peroxide can include any combination of peroxides listed above.

The chemistry supply system 130 can comprise a rinsing chemistry assembly (not shown) for providing rinsing chemistry for generating supercritical rinsing solutions within the processing chamber 108. The rinsing chemistry can include one or more organic solvents including, but not limited to, alcohols and ketones. For example, the rinsing chemistry can comprise solvents, such as N,N-dimethylacetamide (DMAc), gamma-butyrolactone (BLO), dimethyl sulfoxide (DMSO), ethylene carbonate (EC), N-methylpyrrolidone (NMP), dimethylpiperidone, propylene carbonate, and alcohols (such a methanol, ethanol and 2-propanol).

Moreover, the chemistry supply system 130 can be configured to introduce treating chemistry for curing, cleaning, healing (or restoring the dielectric constant of low-k materials), or sealing, or any combination of low dielectric constant films (porous or non-porous). The chemistry can include hexamethyldisilazane (HMDS), chlorotrimethylsilane (TMCS), trichloromethylsilane (TCMS), dimethylsilyldiethylamine (DMSDEA), tetramethyidisilazane (TMDS), trimethylsilyldimethylamine (TMSDMA), dimethylsilyldimethylamine (DMSDMA), trimethylsilyldiethylamine (TMSDEA), bistrimethylsilyl urea (BTSU), bis(dimethylamino)methyl silane (B[DMA]MS), bis (dimethylamino)dimethyl silane (B[DMA]DS), HMCTS, dimethylaminopentamethyidisilane (DMAPMDS), dimethylaminodimethyldisilane (DMADMDS), disila-aza-cyclopentane (TDACP), disila-oza-cyclopentane (TDOCP), methyltrimethoxysilane (MTMOS), vinyltrimethoxysilane (VTMOS), or trimethylsilylimidazole (TMSI). Additionally, the chemistry may include N-tert-butyl-1,1-dimethyl-1-(2,3,4,5-tetramethyl-2,4-cyclopentadiene-1-yl) silanamine, 1,3-diphenyl-1,1,3,3-tetramethyldisilazane, or tert-butylchlorodiphenylsilane. For further details, see U.S. patent application Ser. No. 10/682,196, filed Oct. 10, 2003, and titled “METHOD AND SYSTEM FOR TREATING A DIELECTRIC FILM”, and U.S. patent application Ser. No. 10/379,984, filed Mar. 4, 2003, and titled “METHOD OF PASSIVATING LOW DIELECTRIC MATERIALS IN WAFER PROCESSING”, both incorporated by reference herein.

The processing system 100 can comprise a high-pressure fluid supply system 140. As shown in FIG. 1, the high-pressure fluid supply system 140 can be coupled to the recirculation system 120 using one or more lines 145, but this is not required. The inlet line 145 can be equipped with one or more back-flow valves, and/or heaters (not shown) for controlling the fluid flow from the high-pressure fluid supply system 140. In alternative embodiments, high-pressure fluid supply system 140 can be configured differently and coupled differently. For example, the high-pressure fluid supply system 140 can be coupled to the process module 110.

The high-pressure fluid supply system 140 can comprise a carbon dioxide source (not shown) and a plurality of flow control elements (not shown) for generating a supercritical fluid. For example, the carbon dioxide source can include a CO₂ feed system, and the flow control elements can include supply lines, valves, filters, pumps, and heaters. The high-pressure fluid supply system 140 can comprise an inlet valve (not shown) that is configured to open and close to allow or prevent the stream of supercritical carbon dioxide from flowing into the processing chamber 108. For example, controller 180 can be used to determine fluid parameters such as pressure, temperature, process time, and flow rate.

The processing system 100 can also comprise a pressure control system 160. As shown in FIG. 1, the pressure control system 160 can be coupled to the process module 110 using one or more lines 165, but this is not required. Line 165 can be equipped with one or more back-flow valves, pumps, and/or heaters (not shown) for controlling the fluid flow to pressure control system 160. In alternative embodiments, pressure control system 160 can be configured differently and coupled differently. For example, the pressure control system 160 can also include one or more pumps (not shown), and a sealing means (not shown) for sealing the processing chamber 108. In addition, the pressure control system 160 can comprise means for raising and lowering the substrate 105 and/or the chuck 118.

In one embodiment, the processing system 100 can also comprise the pressure compensator 170. As shown in the illustrated embodiment, the pressure compensator 170 can be coupled to the process module 110 using one or more lines 172 and can be coupled to the recirculation system using one or more inlet lines 174. In alternative embodiments, the pressure compensator 170 may be coupled to the process module 110 differently and may be coupled to the recirculation system 120 differently. The pressure compensator 170 can comprise means (not shown) for monitoring the pressure and/or temperature of the fluid in the recirculation loop 115. Alternatively, the pressure compensator 170 can comprise means (not shown) for monitoring the pressure and/or temperature of the fluid in the processing chamber 108. The pressure compensator 170 can comprise a balancing means (not shown) for maintaining a pressure differential below a threshold. In an alternative embodiment, a balancing means may not be required.

In addition, the processing system 100 can comprise an exhaust control system 150. Alternatively, an exhaust system may not be required. As shown in FIG. 1, the exhaust control system 150 can be coupled to the process module 110 using one or more lines 155, but this is not required. Line 155 can be equipped with one or more back-flow valves, and/or heaters (not shown) for controlling the fluid flow to the exhaust control system 150. In alternative embodiments, the exhaust control system 150 can be configured differently and coupled differently. The exhaust control system 150 can include an exhaust gas collection vessel (not shown) and can be used to remove contaminants from the processing fluid. Alternatively, the exhaust control system 150 can be used to recycle the processing fluid.

In one embodiment, controller 180 can comprise a processor 182 and a memory 184. Memory 184 can be coupled to processor 182, and can be used for storing information and instructions to be executed by processor 182. Alternatively, different controller configurations can be used. In addition, controller 180 can comprise a port 185 that can be used to couple processing system 100 to another system (not shown). Furthermore, controller 180 can comprise input and/or output devices (not shown).

In addition, one or more of the processing elements (110, 120, 130, 140, 150, 160, 170, and 180) may include memory (not shown) for storing information and instructions to be executed during processing and processors for processing information and/or executing instructions. For example, the memory 184 may be used for storing temporary variables or other intermediate information during the execution of instructions by the various processors in the system. One or more of the processing elements can comprise the means for reading data and/or instructions from a computer readable medium. In addition, one or more of the processing elements can comprise the means for writing data and/or instructions to a computer readable medium.

Memory devices can include at least one computer readable medium or memory for holding computer-executable instructions programmed according to the teachings of the invention and for containing data structures, tables, records, or other data described herein.

The processing system 100 can perform a portion or all of the processing steps of the invention in response to the controller 180 executing one or more sequences of one or more computer-executable instructions contained in a memory. Such instructions may be received by the controller 180 from another computer, a computer readable medium, or a network connection.

Stored on any one or on a combination of computer readable media, the present invention includes software for controlling the processing system 100, for driving a device or devices for implementing the invention, and for enabling the processing system 100 to interact with a human user and/or another system, such as a factory system. Such software may include, but is not limited to, device drivers, operating systems, development tools, and applications software. Such computer readable media further include the computer program product of the present invention for performing all or a portion (if processing is distributed) of the processing performed in implementing the invention.

The term “computer readable medium” as used herein refers to any medium that participates in providing instructions to a processor for execution and/or that participates in storing information before, during, and/or after executing an instruction. A computer readable medium may take many forms, including but not limited to, non-volatile media, volatile media, and transmission media. The term “computer-executable instruction” as used herein refers to any computer code and/or software that can be executed by a processor, that provides instructions to a processor for execution and/or that participates in storing information before, during, and/or after executing an instruction.

Controller 180, processor 182, memory 184 and other processors and memory in other system elements as described thus far can, unless indicated otherwise below, be constituted by components known in the art or constructed according to principles known in the art. The computer readable medium and the computer executable instructions can also, unless indicated otherwise below, be constituted by components known in the art or constructed according to principles known in the art.

Controller 180 can use port 185 to obtain computer code and/or software from another system (not shown), such as a factory system. The computer code and/or software can be used to establish a control hierarchy. For example, the processing system 100 can operate independently, or can be controlled to some degree by a higher-level system (not shown).

The controller 180 can be coupled to the pressure compensator 170 and data can be exchanged between the controller 180 and the pressure compensator 170. The controller 180 can include means for determining the pressure of the processing fluid within processing chamber 108 and other elements in the recirculation loop 115, means for using data from the pressure compensator 170, means for determining a sealing pressure for maintaining a seal between the upper assembly 112 and the lower assembly 116, means for determining a pressure differential between the pressure in the loop and the sealing pressure, means for comparing the pressure differential to a threshold value, and means for altering the sealing pressure and/or the pressure of the processing fluid when the pressure differential is different from the threshold value. For example, the sealing pressure can be decreased when the pressure differential is greater than the threshold value, and the sealing pressure can be increased when the pressure differential is less than the threshold value.

Controller 180 can use pre-process data, process data, and post-process data. For example, pre-process data can be associated with an incoming substrate. This pre-process data can include lot data, batch data, run data, composition data, and history data. The pre-process data can be used to establish an input state for a wafer and/or a current state for a process module. Process data can include process parameters. Post processing data can be associated with a processed substrate.

The controller 180 can use the pre-process data to predict, select, or calculate a set of process parameters to use to process the substrate. For example, this predicted set of process parameters can be a first estimate of a process recipe. A process model can provide the relationship between one or more process recipe parameters or set points and one or more process results. A process recipe can include a multi-step process involving a set of process modules. Post-process data can be obtained at some point after the substrate has been processed. For example, post-process data can be obtained after a time delay that can vary from minutes to days. The controller 180 can compute a predicted state for the substrate based on the pre-process data, the process characteristics, and a process model. For example, a pressure differential model can be used along with a fluid pressure level to compute a predicted sealing pressure during various times in the process.

The controller 180 can be used to monitor and/or control the pressure of the incoming fluids and/or gasses, the pressure of the processing fluids and/or gasses, and the pressure of the exhaust fluids and/or gasses.

It will be appreciated that the controller 180 can perform other functions in addition to those discussed here. The controller 180 can monitor the pressure, temperature, flow, or other variables associated with the processing system 100 and take actions based on these values. For example, the controller 180 can process measured data, such as pressure differential data, display data and/or results on a GUI screen, determine a fault condition, determine a response to a fault condition, and alert an operator and/or another system. In addition, controller 180 can use measured data to determine when a system component, such as a sealing device, has failed or is about to fail.

In a supercritical cleaning/rinsing process, the desired process result can be a process result that is measurable using an optical measuring device, such as a SEM. For example, the desired process result can be an amount of contaminant in a fluid, in a via, or on the surface of a substrate. After one or more supercritical processes, the desired process result can be measured.

In various embodiments, system 100 can be used for processing single and/or multiple substrates, and details concerning one example of a multiple workpiece processing system are disclosed in co-owned and co-pending U.S. patent application Ser. No. 09/704,642, entitled “METHOD AND APPARATUS FOR SUPERCRITICAL PROCESSING OF MULTIPLE WORKPIECES,” filed Nov. 1, 2000, the contents of which are incorporated herein by reference. Furthermore, the details concerning an example of a multiple process semiconductor processing system are disclosed in co-owned and co-pending U.S. patent application Ser. No. 09/704,641, entitled “METHOD AND APPARATUS FOR SUPERCRITICAL PROCESSING OF A WORKPIECE,” filed Nov. 1, 2000, the contents of which are incorporated herein by reference.

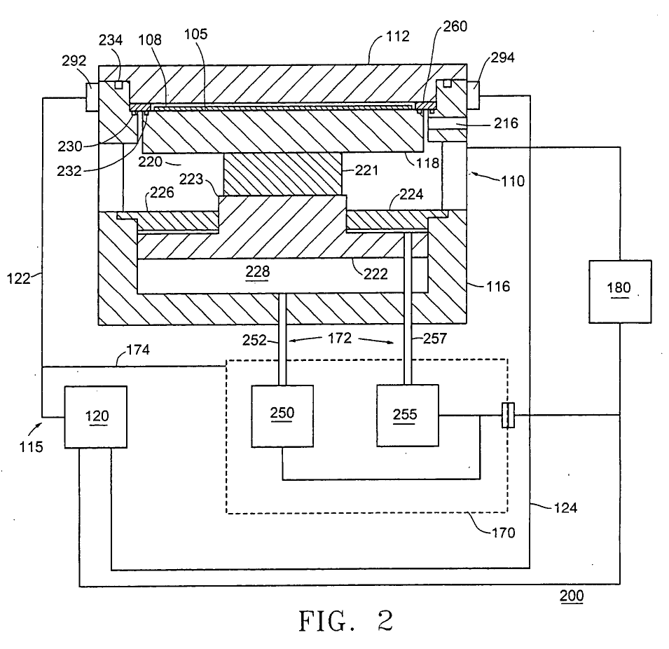

FIG. 2 is a schematic illustration one embodiment of an apparatus for processing a substrate with a processing fluid in accordance with embodiments of the present invention. The apparatus 200 shown in FIG. 2 shows a partial view of some of the elements in the processing system 100 shown in FIG. 1, a schematic view of the pressure compensator 170, and a cross-sectional view of the process module 110.

As shown in the illustrated embodiment, the process module 110 can comprise the upper assembly 112, lower assembly 116, platen (e.g., holder or chuck) 118 configured to support substrate 105, and drive mechanism 220 configured to raise and lower platen 118 between a substrate loading/unloading position and a substrate processing position. Drive mechanism 220 can further include a drive cylinder 221, drive piston 222 having piston neck 223, sealing plate 224, pneumatic cavity 226, and hydraulic cavity 228. Additionally, process module 110 further includes a plurality of sealing devices 230, 232, and 234 for providing a sealed, high-pressure processing chamber 108 in the process module 110.

In addition, the apparatus 200 includes means for forming the processing chamber 108 including a drive mechanism 220 for moving the platen 118 in and out of contact with the upper assembly 112 and for applying a sealing force when the platen 118 is in contact with the upper assembly 112. For example, during operation, the drive mechanism 220 can cause a sealing surface of the platen 118 to contact a sealing surface of the upper assembly 112 to form the processing chamber 108.

The lower assembly 116 and portions of the drive piston 222 can form the hydraulic chamber 228 that can be part of the drive mechanism 220. The lower assembly 116, the sealing plate 224, and portions of the drive piston 222 can form a pneumatic cavity 226 between the drive piston 222 and the sealing plate 224. It will be readily apparent to one skilled in the art that a piston seal between the drive piston 222 and the lower assembly 116 isolates the hydraulic chamber 228 from the pneumatic cavity 226. Further, it will be readily apparent to one skilled in the art that a neck seal, between the piston neck 223 and the sealing plate 224, and a plate seal, between the sealing plate 224 and the lower assembly 116, isolate the pneumatic cavity 226 from atmosphere.

As shown in FIG. 2, the apparatus 200 includes a recirculation loop 115 that can be coupled to both a fluid inlet means 292 and a fluid outlet means 294. The fluid inlet means 292 and the fluid outlet means 294 can be configured to allow the processing fluid to move into and out of the processing chamber 108. For example, fluid inlet means 292 can comprise one or more inlet ports (not shown) configured in a ring 260 that is positioned at a peripheral edge of the processing chamber 108, and the fluid outlet means 294 can comprise one or more outlet ports (not shown) configured in a top surface of the processing chamber 108. In addition, the fluid inlet means 292 and the fluid outlet means 294 can be configured to impart azimuthal momentum, or axial momentum, or both, as well as radial momentum to the flow of high pressure fluid through processing chamber 108 above substrate 105.

In addition, the apparatus 200 includes balancing means 250 and a supply line 252 coupling the balancing means 250 to the hydraulic chamber 228. In one embodiment, balancing means 250 can be part of the pressure compensator 170. Alternatively, balancing means may be part of the pressure control system 160.

Balancing means 250 controls the amount of hydraulic fluid in the hydraulic chamber 228. Increasing the amount of hydraulic fluid in the hydraulic chamber 228 can cause the drive piston 222 to move upwards so that the platen 108 is moved toward the upper assembly 112, and decreasing the amount of hydraulic fluid in the hydraulic chamber 228 can cause the drive piston 222 to move downwards so that the platen 108 is moved away from the upper assembly 112. Controller 180 can be coupled to balancing means 250 and can be used to monitor and/or control the balancing means 250. For example, controller 180 can instruct balancing means to increase the amount, decrease the amount, or maintain the current amount of hydraulic fluid in the hydraulic chamber 228.

The balancing means 250 can comprise means for maintaining a pressure differential below a threshold and for substantially balancing the sealing force relative to a pressure of a processing fluid within the processing chamber 108 during processing of the substrate 105 to thereby maintain the processing chamber 108.

In one embodiment, the controller 180 can provide instructions to the balancing means 250, and the balancing means 250 maintains a pressure differential below a threshold such that the platen 118 does not substantially bend or bow during processing while maintaining a secure contact between the platen 118 and the upper assembly 112. A threshold can be established to reduce the amplitude of relative motion between the platen 118 and the injection ring 260 while the platen 118 contacts the injection ring 260 thereby reducing the number of particles generated during opening and closing of the processing chamber 108.

In another embodiment, a threshold can be established to reduce the amount of pressure applied to the substrate 105 during processing while the substrate 105 contacts the platen 118 thereby reducing the number of particles generated during opening and closing of the processing chamber 108. In still further embodiments, in which a pressure differential is defined as a difference between a pressure used to maintain the processing chamber 108 and a pressure generated within the processing chamber 108, the pressure differential is kept above a first threshold to ensure that the processing chamber 108 is maintained during processing and below a second threshold to reduce the number of particles generated during opening and closing of the processing chamber 108.

In one embodiment, the balancing means 250 can be controlled in response to a pressure of the fluid in the recirculation loop 115. In an alternative embodiment, the balancing means 250 can be controlled in response to a pressure of the fluid in either recirculation loop 115 or the processing chamber 108.

In one embodiment of the invention, the apparatus 200 includes one or more pressure sensors (not shown) for sensing a pressure of a fluid in the processing chamber 108 and/ or a pressure of a fluid in the recirculation loop 115, the sensors being coupled to the balancing means 250. Any type of pressure sensors or transducers, such as but not limited to gage sensors, vacuum sensors, differential pressure sensors, absolute pressure sensors, barometric sensors, piezoelectric pressure sensors, variable-impedance transducers, and resistive pressure sensors, can be suitable for implementing the present invention. In response to the sensed pressure, the system can adjust a force generated by the balancing means 250 to maintain constant contact between the platen 118 and the ring 260 by minimizing or without imparting any bending or bowing. In the one embodiment of invention, the motivating means comprises a piston force.

Furthermore, the apparatus 200 includes a pneumatic controller 255 coupled by a supply line 257 to the pneumatic chamber 226. In one embodiment, pneumatic controller 255 can be part of the pressure compensator 170. Alternatively, pneumatic controller 255 may be part of the pressure control system 160. In one embodiment, the supply lines 252 and 257 together form the one or more supply lines 172 shown in FIG. 1.

The pneumatic controller 255 can control the amount of pneumatic fluid in the pneumatic chamber 226. Increasing the amount of pneumatic fluid in the pneumatic chamber 226 can cause the drive piston 222 to move downwards, and decreasing the amount of pneumatic fluid in the pneumatic chamber 226 can allow the drive piston 222 to move upwards. Controller 180 can be coupled to pneumatic controller 255 and can be used to monitor and/or control the pneumatic controller 255. For example, controller 180 can instruct the pneumatic controller to increase the amount, decrease the amount, or maintain the current amount of pneumatic fluid in the pneumatic chamber 226.

Before supercritical processing, a substrate 105 can be loaded through the slit 216 and onto the platen 118. The processing chamber 108 can be formed by pressurizing the hydraulic cavity 228 to drive the drive piston 222. In one embodiment of the invention, the pneumatic cavity 226 is vented to atmospheric pressure while the hydraulic cavity 228 is sufficiently pressurized with the hydraulic fluid to drive the platen 118 into the spacer/injection ring 260 and the upper chamber assembly 214 to form the processing chamber 108. The processing chamber 108 can then be pressurized, and one or more supercritical processes can be performed on the substrate 105. It should be readily apparent to one skilled in the art that the processing chamber 108 of the present invention is also appropriate for high pressure processing that is below supercritical conditions.

After the supercritical processing, the processing chamber 108 can be vented to a lower pressure, such as atmospheric pressure, by, for example, reducing the pressure of the hydraulic fluid in the hydraulic cavity 228. The pneumatic cavity 226 can also be slightly pressurized, for example, with a gas, which moves the drive mechanism 220 down. This lowers the platen 118 so that the substrate 105 is adjacent to a slit 216. The substrate 105 can then be removed through the slit 216 using a robotic mechanism (not shown), by an operator, or by using other means.

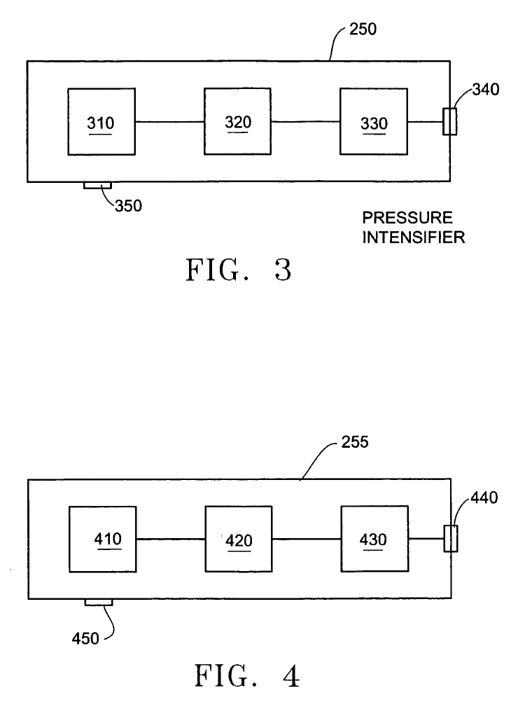

FIG. 3 illustrates a simplified block diagram of a balancing means 250 in accordance with an embodiment of the invention. In the illustrated embodiment, the balancing means 250 shown includes a source 310, a pump 320, a pressure balancer 330, an output element 340, and a control port 350. In alternative embodiments, different configurations can be used. For example, a pressure intensifier may not be required.

Source 310 can comprise a fluid supply source (not shown) and can be used to provide hydraulic fluid or another pressure control fluid. For example, the source 310 may include a storage tank (not shown). The source 310 can be coupled to the pump 320. Alternatively, the source 310 and the pump 320 may be coupled differently. In other embodiments, the source 310 may include heaters, valves, pumps, sensors, regulators, couplings, filters, and/or pipes (not shown).

In one embodiment, the balancing means 250 can comprise the pump 320. The pump 320 can be used to flow and/or increase the pressure of the hydraulic fluid in the balancing means 250. The pump 320 can be coupled to a pressure balancer 330. Alternatively, the pump 320 and the pressure balancer 330 may be coupled differently. In other embodiments, the pump 320 may include heaters, valves, sensors, regulators, couplings, filters, and/or pipes (not shown).

In one embodiment, the balancing means 250 can comprise a pressure balancer 330. The pressure balancer 330 can be used to control, maintain, and/or regulate the pressure of the hydraulic fluid being provided by the balancing means 250. The pressure balancer 330 can be coupled to an output element 340. Alternatively, the pressure balancer 330 and the output element 340 may be coupled differently. In one example, the pressure balancer 330 can comprise a pressure intensifier for increasing the pressure of the hydraulic fluid. In another example, the pressure balancer 330 can include a holding tank for maintaining a substantially constant output pressure from the balancing means 250 during operation. In other embodiments, the pressure balancer 330 may include heaters, valves, sensors, regulators, couplings, filters, and/or pipes (not shown).

In one embodiment, the balancing means 250 can comprise an output element 340. The output element 340 can be used for controlling the flow from the balancing means 250. For example, the output element 340 can comprise a fluid switch (not shown) for controlling the output from the balancing means 250. Controller 180 (FIG. 1) can be coupled to the output element 340 and it can be used to determine when to flow fluid from the balancing means 250. In an alternative embodiment, the output element 340 may include temperature, pressure, and/or flow sensors. In other embodiments, the output element 340 may include heaters, valves, filters, couplings, and/or pipes (not shown).

Output element 340 can be used to couple the balancing means 250 to a processing module (110 FIG. 1) and can be used to control the flow of hydraulic fluid between the balancing means 250 and one or more hydraulic chambers in the processing module (110 FIG. 1). In certain embodiments, the output element 340 includes a flow-control means (not shown). For example, the flow-control means can comprise a valve, a pneumatic actuator, an electric actuator, a hydraulic actuator and/or a micro-electric actuator, or combination thereof. The balancing means 250 can have an operating pressure up to 10,000 psi, and an operating temperature up to 300 degrees Celsius.

In one embodiment, the balancing means 250 can comprise a control port 350. The control port 350 can be used to couple the balancing means 250 to a controller (such as controller 180 FIG. 1) and can be used to pass information between the balancing means 250 and the controller 180. During substrate processing, providing hydraulic fluids that are at an incorrect pressure and/or temperature can have a negative effect on the process, and can affect the process chemistry, process dropout, and process uniformity.

In another embodiment, balancing means 250 may be used during a maintenance or system cleaning operation in which cleaning chemistry is used to remove process by-products and/or particles from the interior surfaces of the processing system 100. This is a preventative maintenance operation in which maintaining low contaminant levels and correct temperatures prevents material from adhering to the interior surfaces of the processing system 100 that can be dislodged later during processing and that can cause unwanted particle deposition on a substrate.

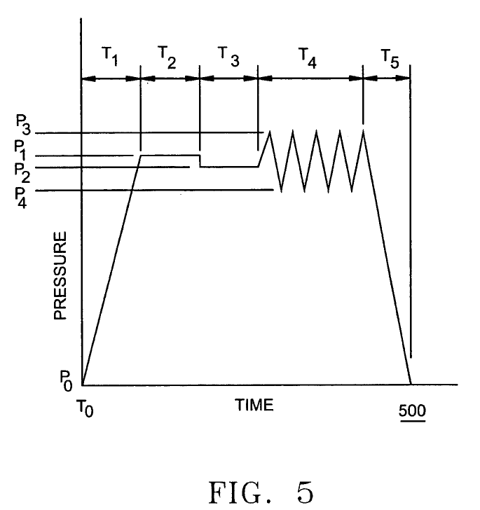

FIG. 4 illustrates a simplified block diagram of a pneumatic controller in accordance with an embodiment of the invention. In the illustrated embodiment, the pneumatic controller 255 is shown that includes a source 410, a pump 420, a pressure balancer 430, an output element 440, and a control port 450. In alternative embodiments, different configurations can be used. For example, a pressure intensifier may not be required.

Source 410 can comprise a fluid supply source (not shown) and can be used to provide hydraulic fluid or another pressure control fluid. For example, the source 410 may include a storage tank (not shown). The source 410 can be coupled to the pump 420. Alternatively, the source 410 and the pump 420 may be coupled differently. In other embodiments, the source 410 may include heaters, valves, pumps, sensors, regulators, couplings, filters, and/or pipes (not shown).

In one embodiment, the pneumatic controller 255 can comprise the pump 420. The pump 420 can be used to flow and/or increase the pressure of the hydraulic fluid in the pneumatic controller 255. The pump 420 can be coupled to the pressure balancer 430. Alternatively, the pump 420 and the pressure balancer 430 may be coupled differently. In other embodiments, the pump 420 may include heaters, valves, sensors, regulators, couplings, filters, and/or pipes (not shown).

In one embodiment, the pneumatic controller 255 can comprise the pressure balancer 430. The pressure balancer 430 can be used to control, maintain, and/or regulate the pressure of the pneumatic fluid being provided by the pneumatic controller 255. The pressure balancer 430 can be coupled to the output element 440. Alternatively, the pressure balancer 430 and the output element 440 may be coupled differently. In one example, the pressure balancer 430 can comprise a pressure intensifier for increasing the pressure of the pneumatic fluid. In another example, the pressure balancer 430 can include a holding tank for maintaining a substantially constant output pressure from the pneumatic controller 255 during operation. In other embodiments, the pressure balancer 430 may include heaters, valves, sensors, regulators, couplings, filters, and/or pipes (not shown).

In one embodiment, the pneumatic controller 255 can comprise an output element 440. The output element 440 can be used for controlling the flow from the pneumatic controller 255. For example, the output element 440 can comprise a fluid switch (not shown) for controlling the output from the pneumatic controller 255. Controller 180 (FIG. 1) can be coupled to the output element 440 and can be used to determine when to flow fluid from the pneumatic controller 255. In an alternative embodiment, the output element 440 may include temperature, pressure, and/or flow sensors. In other embodiments, the output element 440 may include heaters, valves, filters, couplings, and/or pipes (not shown).

Output element 440 can be used to couple the pneumatic controller 255 to a processing module (110 FIG. 1) and can be used to control the flow of pneumatic fluid between the pneumatic controller 255 and one or more pneumatic cavities (e.g., 226 FIG. 2) in the processing module (110 FIG. 1). The pneumatic controller 255 can have an operating pressure up to 10,000 psi and an operating temperature up to 300 degrees Celsius.

In one embodiment, the pneumatic controller 255 can comprise a control port 450. The control port 450 can be used to couple the pneumatic controller 255 to a controller, such as controller (180 FIG. 1), and can be used to pass information between the pneumatic controller 255 and the controller 180. During substrate processing, providing pneumatic fluids that are at an incorrect pressure and/or temperature can have a negative effect on the process, and can affect the process chemistry, process dropout, and process uniformity.

In another embodiment, pneumatic controller 255 may be used during a maintenance or system cleaning operation in which cleaning chemistry is used to remove process by-products and/or particles from the interior surfaces of the processing system 100 (FIG. 1). This is a preventative maintenance operation in which maintaining low contaminant levels and correct temperatures prevents material from adhering to the interior surfaces of the processing system 100 that can be dislodged later during processing and that can cause unwanted particle deposition on a substrate.

FIG. 5 illustrates an exemplary graph of pressure versus time for a supercritical process step in accordance with an embodiment of the invention. In the illustrated embodiment, a graph 500 of pressure versus time is shown, and the graph 500 can be used to represent a supercritical cleaning process step, a supercritical rinsing process step, or a supercritical curing process step, or a combination thereof. Alternatively, different pressures, different timing, and different sequences may be used for different processes. In addition, although a single time sequence is illustrated in FIG. 5, this is not required for the invention. Alternatively, multi-sequence processes may be used.

Referring to FIGS. 1, 2, 3, 4, and 5, prior to an initial time T₀, the substrate 105 to be processed can be placed within the processing chamber 108 and the processing chamber 108 can be sealed. For example, during cleaning and/or rinsing processes, the substrate 105 can have post-etch and/or post-ash residue thereon. The substrate 105, the processing chamber 108, and the other elements in the recirculation loop 115 can be heated to an operational temperature. For example, the operational temperature can range from 40 to 300 degrees Celsius.

In one embodiment, the pressure compensator 170 can operate during the chamber sealing process and can control the pressure differential during the sealing process. Alternatively, the pressure compensator 170 may not be operated during the sealing process.

During time T₁, the processing chamber 108 and the other elements in the recirculation loop 115 can be pressurized. As illustrated in FIG. 5, from the time T₀ and during the time period T₁, the pressure is linearly increased from P₀ to P₁. During at least one portion of the time T₁, the high-pressure fluid supply system 140 can be coupled into the flow path and can be used to provide temperature controlled carbon dioxide into the processing chamber 108 and/or other elements in the recirculation loop 115. For example, the temperature variation of the temperature-controlled carbon dioxide can be controlled to be less than approximately ten degrees Celsius during the pressurization process.

In one embodiment, the pressure compensator 170 can operate during the first portion of the time T₁ and can control the pressure differential during the first portion of the time T₁. Alternatively, the pressure compensator 170 may not be operated during the first portion of the time T₁. For example, controller 180 can instruct the pressure compensator 170 to increase the sealing pressure, decrease the sealing pressure, or maintain the sealing pressure.

During time T₁, a pump (not shown) in the recirculation system 120 can be started and can be used to circulate the temperature-controlled fluid through the processing chamber 108 and the other elements in the recirculation loop 115. In one embodiment, the pressure compensator 170 can operate while the fluid is being circulated and can ensure that the proper pressure differential is maintained while the fluid is being circulated. Alternatively, the pressure compensator 170 may not be operated during this portion of the time T₁.

In one embodiment, when the pressure in the processing chamber 108 exceeds a critical pressure Pc (1,070 psi) (not shown), process chemistry can be injected into the processing chamber 108, using the process chemistry supply system 130. In one embodiment, the high-pressure fluid supply system 140 can be switched off before the process chemistry is injected. Alternatively, the high-pressure fluid supply system 140 can be switched on while the process chemistry is injected.

In other embodiments, process chemistry may be injected into the processing chamber 108 before the pressure exceeds the critical pressure Pc (1,070 psi) using the process chemistry supply system 130. For example, the injection(s) of the process chemistries can begin upon reaching about 1100-1200 psi. In other embodiments, process chemistry is not injected during the T₁ period.

In one embodiment, process chemistry is injected in a linear fashion (e.g., during regular time intervals) during one recirculation cycle, the injection time can be based on the time required for a single recirculation cycle, and the recirculation cycle time can be determined based on the recirculation loop volume and the fluid flow rate. For example, recirculation cycle (injection) times can vary from approximately one second to approximately one hundred minutes. In other embodiments, cleaning chemistry may be injected in a non-linear fashion (e.g., during non-regular time intervals). For example, cleaning chemistry can be injected in one or more steps having different lengths of time and occurring at different times.

The process chemistry can include a cleaning agent, a rinsing agent, or a curing agent, or a combination thereof that is injected into the supercritical fluid. One or more injections of process chemistries can be performed over the duration of time T₁ to generate a supercritical processing solution with the desired concentrations of chemicals. The process chemistry, in accordance with the embodiments of the invention, can also include one more or more carrier solvents.

Still referring to FIGS. 1, 2, 3, 4, and 5, during a second time T₂, the supercritical processing solution can be re-circulated over the substrate and through the processing chamber 108 using the recirculation system 120, such as described above. In one embodiment, the high-pressure fluid supply system 140 can be switched off, and process chemistry is not injected during the second time T₂. Alternatively, the high-pressure fluid supply system 140 can be switched on, and process chemistry may be injected into the processing chamber 108 during the second time T₂ or after the second time T₂.

The processing chamber 108 can operate at a pressure above 1,500 psi during the second time T₂. For example, the pressure can range from approximately 2,500 psi to approximately 3,100 psi, but can be any value so long as the operating pressure is sufficient to maintain supercritical conditions. The supercritical processing solution is circulated over the substrate 105 and through the processing chamber 108 using the recirculation system 120, such as described above. The supercritical conditions within the processing chamber 108 and the other elements in the recirculation loop 115 are maintained during the second time T₂, and the supercritical processing solution continues to be circulated over the substrate 105 and through the processing chamber 108 and the other elements in the recirculation loop 115. The recirculation system 120 can be used to regulate the flow of the supercritical processing solution through the processing chamber 108 and the other elements in the recirculation loop 115.

In one embodiment, the pressure compensator 170 can operate while the supercritical processing solution is being re-circulated. Alternatively, the pressure compensator 170 may not be operated while the supercritical processing solution is being re-circulated. The pressure compensator 170 can be used to control the sealing pressure while the supercritical processing solution is being re-circulated.

Still referring to FIGS. 1, 2, 3, 4, and 5, during a third time T₃, one or more push-through processes can be performed. The high-pressure fluid supply system 140 can comprise means for providing a first volume of temperature-controlled fluid during a push-through process, and the first volume can be larger than the volume of the recirculation loop 115. Alternatively, the first volume can be less than or approximately equal to the volume of the recirculation loop 115. In addition, the temperature differential within the first volume of temperature-controlled fluid during the push-through process can be controlled to be less than approximately ten degrees Celsius. Alternatively, the temperature variation of the temperature-controlled fluid can be controlled to be less than approximately five degrees Celsius during a push-through process.

In other embodiments, the high-pressure fluid supply system 140 can comprise means for providing one or more volumes of temperature controlled fluid during a push-through process; each volume can be larger than the volume of the processing chamber 108 or the volume of the recirculation loop 115; and the temperature variation associated with each volume can be controlled to be less than ten degrees Celsius.

For example, during the third time T₃, one or more volumes of temperature controlled supercritical carbon dioxide can be fed into the processing chamber 108 and the other elements in the recirculation loop 115 from the high-pressure fluid supply system 140, and the supercritical cleaning solution along with process residue suspended or dissolved therein can be displaced from the processing chamber 108 and the other elements in the recirculation loop 115 through the exhaust control system 150. In an alternative embodiment, supercritical carbon dioxide can be fed into the recirculation system 120 from the high-pressure fluid supply system 140, and the supercritical cleaning solution along with process residue suspended or dissolved therein can also be displaced from the processing chamber 108 and the other elements in the recirculation loop 115 through the exhaust control system 150.

Providing temperature-controlled fluid during the push-through process prevents process residue suspended or dissolved within the fluid being displaced from the processing chamber 108 and the other elements in the recirculation loop 115 from dropping out and/or adhering to the processing chamber 108 and the other elements in the recirculation loop 115. In addition, during the third time T₃, the temperature of the fluid supplied by the high-pressure fluid supply system 140 can vary over a wider temperature range than the range used during the second time T₂.

In one embodiment, the pressure compensator 170 can operate during a push-through process. Alternatively, the pressure compensator 170 may not be operated during a push-through process. The pressure compensator 170 can be used to control the sealing pressure during a push-through process.

In the graph 500 shown in FIG. 5, a single second time T₂ is followed by a single third time T₃, but this is not required. In alternative embodiments, other time sequences may be used to process a substrate.

Still referring to FIGS. 1, 2, 3, 4, and 5, after the push-through process is complete, a pressure cycling process can be performed. Alternatively, one or more pressure cycles can occur during the push-through process. In other embodiments, a pressure cycling process is not required. During a fourth time T₄, the processing chamber 108 can be cycled through a plurality of decompression and compression cycles. The pressure can be cycled between a first pressure P₃ and a second pressure P₄ one or more times. In alternative embodiments, the first pressure P₃ and a second pressure P₄ can vary. In one embodiment, the pressure can be lowered by venting through the exhaust control system 150. For example, this can be accomplished by lowering the pressure to below approximately 1,500 psi and raising the pressure to above approximately 2,500 psi. The pressure can be increased by using the high-pressure fluid supply system 140 to provide additional high-pressure fluid.

The high-pressure fluid supply system can comprise means for providing a first volume of temperature-controlled fluid during a compression cycle, and the first volume can be larger than the volume of the recirculation loop 115. Alternatively, the first volume can be less than or approximately equal to the volume of the recirculation loop 115. In addition, the temperature differential within the first volume of temperature-controlled fluid during the compression cycle can be controlled to be less than approximately ten degrees Celsius. Alternatively, the temperature variation of the temperature-controlled fluid can be controlled to be less than approximately five degrees Celsius during a compression cycle.

In addition, the high-pressure fluid supply system 140 can comprise means for providing a second volume of temperature-controlled fluid during a decompression cycle, and the second volume can be larger than the volume of the recirculation loop 115. Alternatively, the second volume can be less than or approximately equal to the volume of the recirculation loop 115. In addition, the temperature differential within the second volume of temperature-controlled fluid during the decompression cycle can be controlled to be less than approximately ten degrees Celsius. Alternatively, the temperature variation of the temperature-controlled fluid can be controlled to be less than approximately five degrees Celsius during a decompression cycle.

In other embodiments, the high-pressure fluid supply system can comprise means for providing one or more volumes of temperature controlled fluid during a compression cycle and/or decompression cycle; each volume can be larger than the volume of the processing chamber or the volume of the recirculation loop 115; the temperature variation associated with each volume can be controlled to be less than ten degrees Celsius; and the temperature variation can be allowed to increase as additional cycles are performed.

Furthermore, during the fourth time T₄, one or more volumes of temperature controlled supercritical carbon dioxide can be fed into the processing chamber 108 and the other elements in the recirculation loop 115 from the high-pressure fluid supply system 140, and the supercritical cleaning solution along with process residue suspended or dissolved therein can be displaced from the processing chamber 108 and the other elements in the recirculation loop 115 through the exhaust control system 150. In an alternative embodiment, the supercritical carbon dioxide can be fed into the recirculation system 120 from the high-pressure fluid supply system 140, and the supercritical cleaning solution along with process residue suspended or dissolved therein can also be displaced from the processing chamber 108 and the other elements in the recirculation loop 115 through the exhaust control system 150.

Providing temperature-controlled fluid during the pressure cycling process prevents process residue suspended or dissolved within the fluid being displaced from the processing chamber 108 and the other elements in the recirculation loop 115 from dropping out and/or adhering to the processing chamber 108 and the other elements in the recirculation loop 115. In addition, during the fourth time T₄, the temperature of the fluid supplied by the high-pressure fluid supply system 140 can vary over a wider temperature range than the range used during the second time T₂.

In the graph 500 shown in FIG. 5, a single third time T₃ is followed by a single fourth time T₄, but this is not required. In alternative embodiments, other time sequences may be used to process a substrate.

In an alternative embodiment, the high-pressure fluid supply system 140 can be switched off during a portion of the fourth time T₄. For example, the high-pressure fluid supply system 140 can be switched off during a decompression cycle.

Still referring to FIGS. 1, 2, 3, 4, and 5, during a fifth time T₅, the processing chamber 108 can be returned to a lower pressure. For example, after the pressure cycling process is completed, then the processing chamber 108 can be vented or exhausted to atmospheric pressure.

The high-pressure fluid supply system 140 can comprise means for providing a volume of temperature-controlled fluid during a venting process, and the volume can be larger than the volume of the recirculation loop. Alternatively, the volume can be less than or approximately equal to the volume of the recirculation loop 115. In addition, the temperature differential within the volume of temperature-controlled fluid during the venting process can be controlled to be less than approximately twenty degrees Celsius.

In other embodiments, the high-pressure fluid supply system 140 can comprise means for providing one or more volumes of temperature controlled fluid during a venting process; each volume can be larger than the volume of the processing chamber 108 or the volume of the recirculation loop 115; the temperature variation associated with each volume can be controlled to be less than twenty degrees Celsius; and the temperature variation can be allowed to increase as the pressure approaches a final pressure used to process the substrate 105 within the processing chamber 108.

Furthermore, during the fifth time T₅, one or more volumes of temperature controlled supercritical carbon dioxide can be fed into the processing chamber 108 and the other elements in the recirculation loop 115 from the high-pressure fluid supply system 140, and the remaining supercritical cleaning solution along with process residue suspended or dissolved therein can be displaced from the processing chamber 108 and the other elements in the recirculation loop 115 through the exhaust control system 150. In an alternative embodiment, the supercritical carbon dioxide can be fed into the recirculation system 120 from the high-pressure fluid supply system 140, and the remaining supercritical cleaning solution along with process residue suspended or dissolved therein can also be displaced from the processing chamber 108 and the other elements in the recirculation loop 115 through the exhaust control system 150.

Providing temperature-controlled fluid during the venting process prevents process residue suspended or dissolved within the fluid being displaced from the processing chamber 108 and the other elements in the recirculation loop 115 from dropping out and/or adhering to the processing chamber 108 and the other elements in the recirculation loop 115.

In the graph 500 shown in FIG. 5, a single fourth time T₄ is followed by a single fifth time T₅, but this is not required. In alternative embodiments, other time sequences may be used to process a substrate.

In one embodiment, during a portion of the fifth time T₅, the high-pressure fluid supply system 140 can be switched off. In addition, the temperature of the fluid supplied by the high-pressure fluid supply system 140 can vary over a wider temperature range than the range used during the second time T₂. For example, the temperature can range below the temperature required for supercritical operation.

For substrate processing, the chamber pressure can be made substantially equal to the pressure inside of a transfer chamber (not shown) coupled to the processing chamber 108. In one embodiment, the substrate 105 can be moved from the processing chamber 108 into the transfer chamber, and moved to a second process apparatus or module to continue processing.

In the illustrated embodiment shown in FIG. 3, the pressure returns to an initial pressure P₀, but this is not required for the invention. In alternative embodiments, the pressure does not have to return to P₀, and the process sequence can continue with additional time steps such as those shown in time steps T₁, T₂, T₃, T₄, or T₅ . During the time step T₂, the pressure is maintained at approximately P₁, and during the time step T₃, the pressure is maintained at approximately P₂.

The graph 500 is provided for exemplary purposes only. It will be understood by those skilled in the art that a supercritical processing step can have any number of different time/pressures or temperature profiles without departing from the scope of the invention. Further, any number of cleaning, rinsing, and/or curing process sequences with each step having any number of compression and decompression cycles are contemplated. In addition, as stated previously, concentrations of various chemicals and species within a supercritical processing solution can be readily tailored for the application at hand and altered at any time within a supercritical processing step.

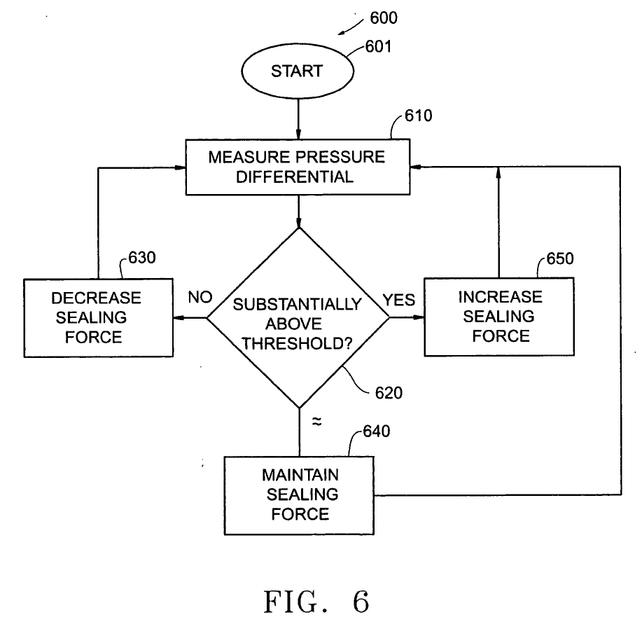

FIG. 6 illustrates a flow diagram 600 of a method of operating a pressure compensator in accordance with an embodiment of the invention. In the illustrated embodiment, the flow diagram comprises a number of steps, though not all are required for the invention. Alternatively, a different number of steps and/or different types of processes may be included.

First, in the step 601, the process starts. In the step 610, a pressure differential can be measured. In one embodiment, the pressure differential is measured for the chamber pressure and a pressure in a sealing device, such as a hydraulic chamber. For example, one or more piston arrangements can be used to seal a high-pressure processing chamber and to maintain the seal during high-pressure processes that include supercritical processing steps.

In the step 620, the pressure differential (e.g., the pressure within the processing chamber 108 minus the sealing pressure to maintain the processing chamber 108) is compared to a threshold value. The comparison can be made during different parts of a process and the threshold values and the pressure differential can be different during these different parts of the process. For example, comparisons can be made during sealing steps, during pressurization steps, during injection steps, during recirculation steps, during push-through steps, during pressure cycling steps, and during venting steps. A query can be performed to determine if the pressure differential requires a change.

When the pressure differential is substantially below the threshold value, the procedure 600 branches to the step 630; when the pressure differential is approximately equal to the threshold value, the procedure 600 branches to the step 640; and when the pressure differential is substantially above the threshold value, the procedure 600 branches to the step 650.

In the step 630, the pressure differential can be increased. For example, the pressure differential can be smaller than is required for a particular process step and the sealing force and/or sealing pressure can be decreased. In another example, the pressure within the processing chamber 108 can be increased.

In the step 640, the pressure differential can be maintained. For example, the pressure differential can be within the required limits for a particular process step and the sealing force and/or sealing pressure can be maintained.

In the step 650, the pressure differential can be decreased. For example, the pressure differential can be larger than is required for a particular process step and the sealing force and/or sealing pressure can be increased. In another example, the pressure within the processing chamber 108 can be decreased.

While the invention has been described in terms of specific embodiments incorporating details to facilitate the understanding of the principles of construction and operation of the invention, such reference herein to specific embodiments and details thereof is not intended to limit the scope of the claims appended hereto. It will be apparent to those skilled in the art that modifications may be made in the embodiments chosen for illustration without departing from the spirit and scope of the invention.

What is claimed is:

1. A system for processing a substrate within a high-pressure processing system, the system comprising:
a recirculation loop comprising a high-pressure processing chamber and a high-pressure recirculation system coupled to the high-pressure processing chamber, wherein the high-pressure processing chamber includes a first chamber assembly and a second chamber assembly, the second chamber assembly including a platen, the platen including a region for supporting the substrate;
a drive mechanism for forming the high-pressure processing chamber including means for moving the second chamber assembly in and out of contact with the first chamber assembly and for applying a sealing force when the second chamber assembly is in contact with the first chamber assembly;
a high-pressure fluid supply system coupled to the recirculation loop and comprising means for pressurizing the recirculation loop using a high-pressure fluid;
a pressure compensator coupled to the drive mechanism for controlling a pressure differential; and
a controller coupled to the recirculation loop, the drive mechanism, the high-pressure fluid supply system, and the pressure compensator, the controller comprising means for comparing the pressure differential to a threshold and means for controlling the pressure differential.

2. The system of claim 1, wherein the controller further comprises:
means for determining a bending pressure threshold for the platen; and
means for instructing the pressure compensator to maintain the pressure differential below the bending pressure threshold such that the platen does not substantially bend during processing of the substrate.

3. The system of claim 1, wherein the controller further comprises:
means for determining the threshold using the sealing force, a chamber pressure, or a recirculation loop pressure, or a combination thereof.

4. The system of claim 1, wherein the controller further comprises:
means for determining the threshold using a process recipe, a sealing pressure, a chamber pressure, or a recirculation loop pressure, or a combination thereof.

5. The system of claim 1, wherein the controller further comprises:
means for substantially balancing the sealing force relative to a pressure of a supercritical processing fluid within the recirculation loop during processing of the substrate.

6. The system of claim 1, wherein the controller further comprises:
means for substantially balancing the sealing force relative to a pressure of a supercritical processing fluid within the high-pressure processing chamber during processing of the substrate.

7. The system of claim 6, wherein the controller further comprises:
means for substantially balancing the sealing force relative to a pressure of a processing fluid within the high-pressure processing chamber during a chamber pressurization process, wherein the high-pressure processing chamber and the recirculation loop are pressurized using supercritical CO₂.

8. The system of claim 6, wherein the controller further comprises:
means for substantially balancing the sealing force relative to a pressure of a processing fluid within the high-pressure processing chamber during an injection process, wherein a high-pressure processing fluid is created when process chemistry is injected into supercritical CO₂ flowing through the high-pressure processing chamber and the recirculation loop.

9. The system of claim 8, wherein the controller further comprises:
means for substantially balancing the sealing force relative to a pressure of a processing fluid within the high-pressure processing chamber during a recirculation process, wherein the high-pressure processing fluid is flowed through the high-pressure processing chamber and the recirculation loop.

10. The system of claim 9, wherein the controller further comprises:
means for substantially balancing the sealing force relative to a pressure of a processing fluid within the high-pressure processing chamber during a push-through process, wherein the high-pressure fluid supply system provides an additional volume of supercritical CO₂ that flows through the high-pressure processing chamber and the recirculation loop and displaces substantially all of the high-pressure processing fluid from the high-pressure processing chamber and the recirculation loop.

11. The system of claim 10, wherein the controller further comprises:
means for substantially balancing the sealing force relative to a pressure of a processing fluid within the high-pressure processing chamber during a pressure cycling process, wherein the pressure cycling process comprises at least one decompression cycle and at least one compression cycle, the decompression cycle including a pressure decrease in which the pressure in the high-pressure processing chamber and the recirculation loop is decreased from a first supercritical pressure to a second supercritical pressure, and the compression cycle including a pressure increase in which the pressure in the high-pressure processing chamber and the recirculation loop is increased from the second supercritical pressure to a third supercritical pressure.

12. The system of claim 11, wherein the controller further comprises:
means for substantially balancing the sealing force relative to a pressure of a processing fluid within the high-pressure processing chamber during a venting process, wherein the pressure in the high-pressure processing chamber and the recirculation loop is reduced to a non-supercritical pressure.

13. The system of claim 1, further comprising:
transfer means for positioning the substrate on the platen before forming the high-pressure processing chamber; and
transfer means for removing the substrate from the platen after processing the substrate.

14. The system of claim 1, wherein the pressure compensator comprises:
a balancing means; and
a pneumatic controller.

15. The system of claim 1, further comprising a deflection-prevention means including means for balancing a piston force exerted by a piston on the platen relative to a processing pressure in the processing chamber.

16. The system of claim 1, further comprising a particle-reduction means including means for balancing a piston force exerted by the first piston on the platen relative to a pressure in the processing chamber during a chamber sealing process.

17. A method of processing a substrate within a high-pressure processing system, the method comprising:
positioning a substrate on a substrate holder;
applying a sealing force to bring a first chamber housing into contact with a second chamber housing to form a processing chamber;
pressurizing the processing chamber using a high-pressure fluid;
determining a pressure differential using the sealing force and a pressure within the processing chamber; and
comparing the pressure differential to a threshold and substantially balancing the sealing force relative to the pressure within the processing chamber during processing of the substrate.
